(19) United States
(12) Patent Application Publication
(10) Pub. No.: US 2003/0143410 A1
(43) Pub. Date: Jul. 31, 2003

(54) Method for reduction of contaminants in amorphous-silicon film

(75) Inventors: Tae Kyung Won, San Jose, CA (US); Quanyuan Shang, Saratoga, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/359,955

(22) Filed: Feb. 6, 2003

Related U.S. Application Data
(63) Continuation-in-part of application No. 08/823,608, filed on Mar. 24, 1997, now abandoned.

(51) Int. Cl. C23C 16/00; B32B 9/00

(52) U.S. Cl. 428/448; 427/248.1; 427/255.28; 428/446; 428/698

(57) ABSTRACT

A method of conditioning a chemical vapor deposition chamber prior to a deposition step on a substrate. The method includes passing a deposition gas mixture into the chamber under reaction conditions so as to deposit a layer of amorphous silicon on the interior surfaces in the chamber. Thereafter, a device comprising an amorphous silicon film is manufactured in a chemical vapor deposition chamber.

### CROSS REFERENCE TO RELATED APPLICATION

This application is a continuation-in-part of U.S. application Ser. No. 08/823,608, filed Mar. 24, 1997, which is incorporated by reference herein in its entirety. U.S. application Ser. No. 08/823,608, claims priority to U.S. application Ser. No. 08/416,430, filed Apr. 4, 1995, which is incorporated by reference herein in its entirety.

### FIELD OF THE INVENTION

This invention relates broadly to chemical vapor deposition (CVD) processing. More particularly, this invention relates to conditioning CVD chambers after cleaning the chamber and prior to subsequent CVD processing.

### BACKGROUND OF THE DISCLOSURE

CVD is widely used in the semiconductor industry to deposit films of various kinds, such as intrinsic and doped amorphous silicon, silicon oxide, silicon nitride, silicon oxynitride and the like on a substrate. Modern semiconductor CVD processing is generally done in a vacuum chamber by heating precursor gases that dissociate and react to form the desired film. In order to deposit films at low temperatures and relatively high deposition rates, a plasma can be formed from the precursor gases in the chamber. Such processes are known as plasma enhanced chemical vapor deposition processes, or PECVD.

State of the art CVD chambers are made of aluminum and include a support for the substrate to be processed as well as a port for entry of the required precursor gases. When plasma is used, the gas inlet and/or the substrate support will be connected to a source of power, such as an RF power source. A vacuum pump is also connected to the chamber to control the pressure in the chamber and to remove the various gases and particulates generated during the deposition.

The plasma-enhanced chemical vapor deposition (PECVD) process is the most common deposition method used to obtain device-quality hydrogenated amorphous silicon (a-Si:H) with a low level of atmospheric contamination. In the past, most studies investigated the effect of impurities on the optoelectronic properties of a-Si. It was shown that contaminants such as oxygen and nitrogen in an amorphous conductor can act as dopants and increase the defect density when they rise above a certain concentration. See, for example, Morimoto et al., 1990, Jpn. J. Appl. Phys. 29, L1747; Morimoto et al., 1991, Appl. Phys. Lett. 59, 2130; and Tsai et al., 1984, AIP Conf. Proc. 120, 242. Therefore, a reduction of the film contaminants is desirable to improve device-quality a-Si films that are used in flat panel devices such as thin film transistor liquid crystal displays (TFT-LCDs) and solar cells.

In typical applications, multi-layer films are prepared on substrates. For example, in one such film 100, shown in FIG. 1, a silicon nitride layer 104 is overlaid on substrate 102. A silicon oxide layer 106 is overlaid on the silicon nitride layer 104. Finally, an a-Si layer 108 is overlaid on the silicon oxide layer 106. If all three layers (104, 106 and 108) are deposited onto substrate 102 in the same chamber using conventional techniques, the amount of oxygen contamination in the a-Si layer 108 would exceed 1×10¹⁹ atoms/cubic centimeter. Therefore, such multi-layer films are conventionally prepared using a separate process chamber for the a-Si deposition. The use of multiple process chambers to prepare multi-layer films increases the cost of devices that include such films. This is because valuable manufacturing time is lost transferring the substrate from one process chamber to another.

Thus, given the above background, what is needed in the art are improved methods for manufacturing multi-layer films, such as the films that are used in TFT-LCDs and solar cells.

### SUMMARY OF THE INVENTION

The present invention provides methods for preparing multi-layer films that include an a-Si layer in a single process chamber without introducing unacceptable levels (e.g. above 1×10⁻¹⁹ atoms/cubic centimeter) of oxygen and/or nitrogen into the a-Si layer of such multi-layer films. Using the methods of the present invention, all of the layers of the multi-layer film, including the a-Si layer may be deposited in the same chamber, thereby increasing manufacturing efficiency and reducing production costs of such films.

One embodiment of the present invention provides a method of conditioning, or “seasoning”, a chemical vapor deposition chamber. In the embodiment, prior to a deposition step on a substrate, a deposition gas mixture is passed into the chamber under reaction conditions so as to deposit a layer of amorphous silicon on the interior surfaces in the chamber. In some embodiments, the chemical vapor deposition chamber is a plasma enhanced chemical deposition chamber.

In some embodiments, the pressure in the chamber is between 0.5 Torr and 6.0 Torr, between 1 Torr and 2 Torr, or between 1.2 Torr and 1.5 Torr during a portion of said method of conditioning said chemical vapor deposition chamber. In some embodiments, the susceptor in the chamber is held at a temperature between 275° C. and 475° C., between 325° C. and 450° C., or between 375° C. and 425° C. during a portio of the method for conditioning the chemical vapor deposition chamber.

In some embodiments, the deposition gas mixture includes hydrogen and SiH₄ gas. In some embodiments, a hydrogen gas flow rate into the chamber during a portion of the method for conditioning the chamber is between C₁×1000 and C₁×2500 sccm, or between C₁×1200 and C₁×1800 sccm. Here C₁=[size of the substrate in the chemical vapor deposition chamber/200,000 mm²]. In some embodiments, the SiH₄ gas flow rate into the chamber during a portion of the method for conditioning the chemical vapor deposition chamber is between C₁×100 and C₁×600 sccm or between C₁×200 and C₁×400 sccm. Here, C₁=[size of the substrate in the chemical vapor deposition chamber/200,000 mm²].

In some embodiments the ratio between the gas flow rate of the SiH₄ and the gas flow rate of the hydrogen into the chamber during a portion of the method of conditioning said chemical vapor deposition chamber is between 1:2 and 1:8 (e.g., about 1:4).

In some embodiments in accordance with the present invention, a plasma is formed from the deposition gas mixture using between C₁×200 and C₁1000 Watts of power, or between C₁×400 and C₁×700 Watts of power. Here, C₁=[size of the substrate in the chemical vapor deposition chamber/200,000 mm²]. In some embodiments, the reaction conditions comprise generating plasma for a duration of between 30 seconds and 400 seconds, between 60 seconds and 300 seconds, or between 140 seconds and 225 seconds.

In some embodiments, the inventive method further comprises depositing an amorphous silicon layer on a substrate and cleaning the chemical vapor deposition chamber. In some embodiments, this cleaning step is effected by passing nitrogen fluoride into the chamber and by generating plasma from the nitrogen fluoride.

Another aspect of the invention provides a device comprising an amorphous silicon film. In this aspect of the invention, the device is manufactured in a chemical vapor deposition chamber (e.g., a PECVD chamber). Furthermore, the chemical vapor deposition chamber is conditioned by passing a deposition gas mixture into the chamber under reaction conditions so as to deposit a layer of amorphous silicon on the interior surfaces in the chamber prior to manufacturing the device in the chamber.

In some embodiments the device is a multilayer device that includes a layer of silicon nitride and a layer of silicon oxide in addition to the layer of amorphous silicon. In such embodiments, the amorphous silicon layer, the layer of silicon nitride and the layer of silicon oxide are deposited on a substrate (e.g., glass, quartz, silicon, etc.) without an intervening cleaning or chamber transferring step.

In some embodiments, the device is a multilayer device that includes a layer of silicon oxide in addition to the layer of amorphous silicon. In such embodiments, the amorphous silicon layer and the layer of silicon oxide are deposited on a substrate without an intervening cleaning step or chamber-transferring step.

In some embodiments, the device is a multilayer device that includes a layer of silicon nitride in addition to the layer of amorphous silicon. In such embodiments, the amorphous silicon layer and the layer of silicon nitride are deposited on a substrate without an intervening cleaning step or chamber-transferring step.

In still other embodiments, the device is a multilayer device that includes an insulating film in addition to the layer of amorphous silicon. In such embodiments, the amorphous silicon layer and the insulating film are each sequentially deposited on a substrate without an intervening cleaning step or chamber-transferring step.

### BRIEF DESCRIPTION OF THE DRAWINGS

FIG. 1 is a cross-sectional view of a multi-layer film used in devices in the art.

FIG. 2A is a PECVD chamber in accordance with the prior art.

FIG. 2B is a PECVD chamber in accordance with the prior art.

FIG. 2C is a PECVD chamber in accordance with the prior art.

FIG. 3 discloses a secondary ion mass spectroscopy (SIMS) analysis of an a-Si layer in a structure having the topology shown in FIG. 1 that has been made in a PECVD chamber the has been pretreated with amorphous silicon, in accordance with one embodiment of the invention.

FIG. 4 discloses a secondary ion mass spectroscopy (SIMS) analysis of an a-Si layer in a structure having the topology shown in FIG. 1 that has been made in a PECVD chamber the has been pretreated with silicon oxide, in accordance with one embodiment of the invention.

Like referenced numerals refer to corresponding parts throughout the several views of the drawings.

### DETAILED DESCRIPTION OF THE INVENTION

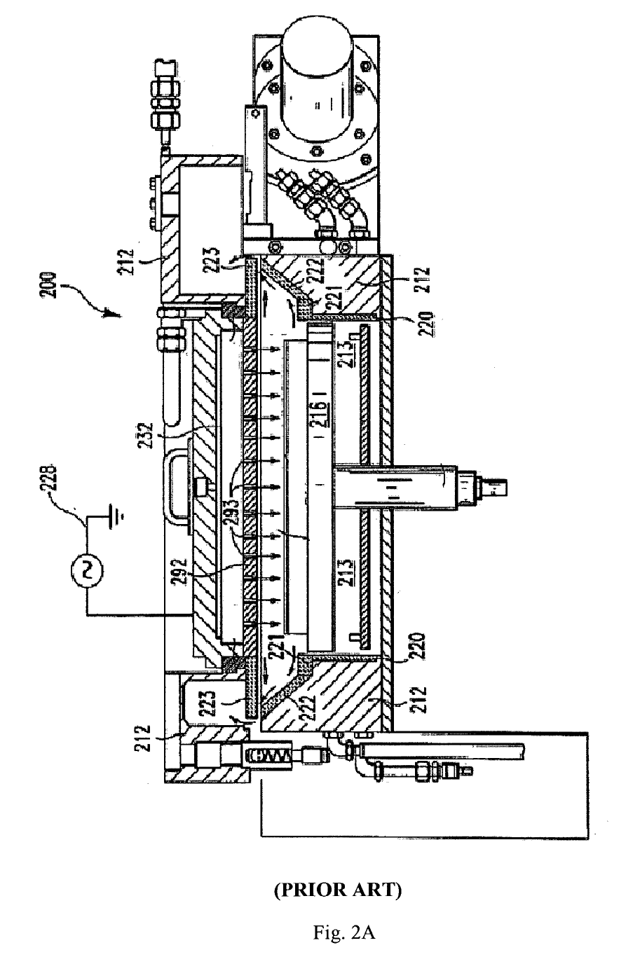

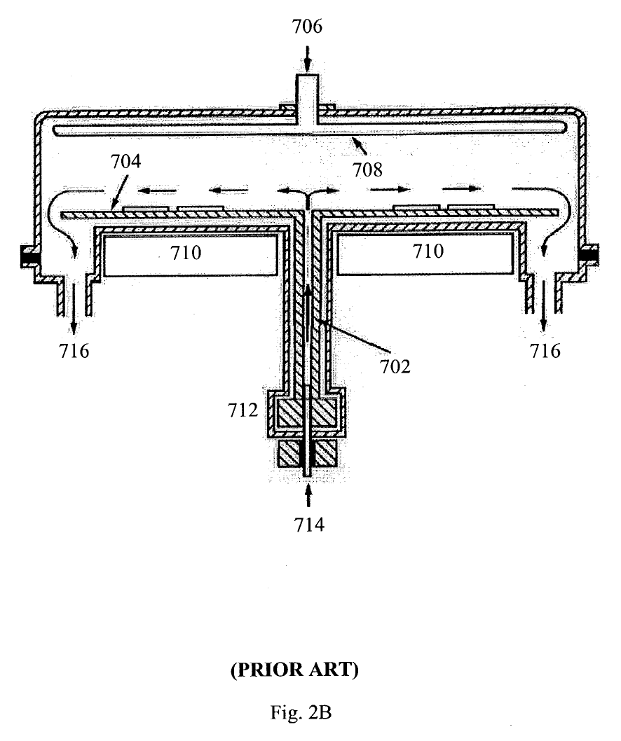

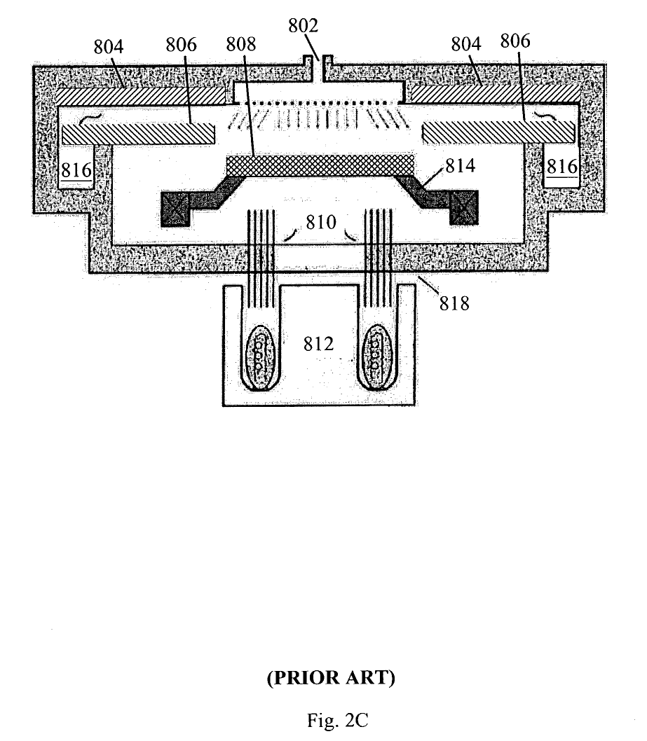

The methods of the present invention can be used in conjunction with a conventional parallel-plate radio-frequency (RF) plasma enhanced chemical vapor deposition (PECVD) reactor, such as reactors (setups) disclosed in FIG. 2A through FIG. 2C. U.S. Pat. No. 5,366,585 to Robertson et al., incorporated herein by reference, discloses a PECVD chamber 200 (FIG. 2A) suitable for processing large area glass plates. Referring now to FIG. 2A, a vacuum chamber 213 surrounded by a reactor housing 212 includes a hinged lid. A gas manifold 232 is situated over and parallel to a susceptor 216 upon which the substrate is mounted during processing. The gas manifold 232 includes a faceplate 292 having a plurality of orifices 293 therein that are used to supply process and purge gases. An RF power supply 228 creates a plasma from the supplied gases.

A set of ceramic or anodized aluminum liners 220, 221 and 222 adjacent to the housing 212 insulate the metal walls of housing 212 so that no arcing occurs between housing 212 and susceptor 216 during plasma processing. These ceramic or anodized aluminum liners 220, 221 and 222 also can withstand fluorine containing etch cleaning gases. A ceramic annulus 223 is also attached to face plate 192 to provide electrical insulation for the faceplate 292. These ceramic parts also repel plasma and thus aid in confining the processing plasma close to the substrate and aid in reducing the amount of deposit build-up on the walls of housing 212.

Examples are provided below in which an AKT 1600 PECVD, susceptor size 400 mm×500 mm (Applied Materials, Santa Clara, Calif.) is used. However, the methods of the present invention can be used to preseason any chamber capable of depositing an amorphous silicon layer. Such chambers include, but are not limited PECVD chambers such as the AKT 1600A CVD, AKT 1600B CVD, AKT 3500 CVD, AKT 3900 CVD, AKT 4300 CVD, AKT 4300A CVD, AKT 5500 CVD, AKT 5500A CVD, AKT 10K CVD, AKT 15K CVD (Applied Materials, Santa Clara, Calif.).

The methods of the present invention can be used in PECVD setups that include a rotating shaft, such as the setup illustrated in FIG. 2B. Furthermore, the methods of the present invention can be used in PECVD setups that include an arrangement f showerhead plate or heating the susceptor from the back with lamps, such as the setup illustrated in FIG. 2C.

The PECVD chamber in FIG. 2B includes a rotating shaft 702 and a rotating susceptor 704. The PECVD chamber in FIG. 2B further includes a shielded RF power input 706, an upper electrode 708, heaters 710, a magnetic rotation drive 712, gas inflow 714, and gas outflow 716. The setup illustrated in FIG. 2C illustrates a PECVD setup that uses a showerhead plate 802 where gases enter. Furthermore, showerhead plate 802 serves as an electrode. The setup illustrated in FIG. 2C further includes an insulator 804, a baffle plate 806, a susceptor 808, support fingers 814, and a vacuum manifold 816. Susceptor 808 is used to hold a wafer. Susceptor 808 is heated by collimated light 810 that originates from a lamp/reflector module 812 and passes through quartz window 818. Although FIGS. 2A through 2C illustrate setups in which the substrate is placed horizontally, the methods of the present invention can be used in setups in which the substrate is placed vertically (not shown).

The methods of the present invention may also be used with CVD apparatus such as the one disclosed in U.S. Pat. No. 6,223,685 entitled “Film to tie up loose fluorine in the chamber after a clean process,” issued to Gupta et al., which is assigned to Applied Materials, Inc., the assignee of the present invention, and is hereby incorporated by reference in its entirety. The methods of the present invention may also be used with the CVD apparatus described in U.S. Pat. No. 5,558,717 entitled “CVD Processing Chamber,” issued to Zhao et al., which is assigned to Applied Materials, Inc., the assignee of the present invention, and is hereby incorporated by reference in its entirety.

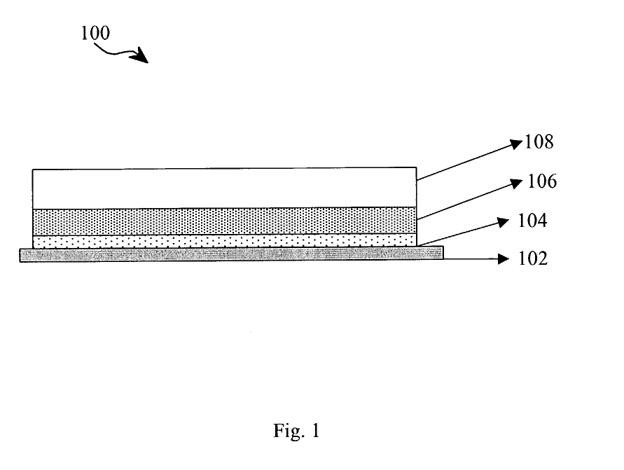

The methods of the present invention provide novel conditioning, or “seasoning”, processes that deposit a thin, inactive solid compound film on the walls and fixtures in the PECVD chamber. The novel process conditions of the present invention are best introduced by describing experiments that were performed to demonstrate the advantages of the present invention. In each of these experiments, a device having the topology illustrated in FIG. 1 was made in a PECVD chamber using the same continuous multi-layer deposition techniques. In the first experiment, the PECVD chamber was pretreated with a novel a-Si pretreatment process before making a device having the topology illustrated in FIG. 1. In the second experiment, the PECVD chamber was pretreated with a SiO method rather than the novel a-Si pretreatment method prior to making a device having the topology illustrated in FIG. 1. In each of the experiments, the a-Si layer (FIG. 1, 108) of the device produced in the PECVD chamber was analyzed by secondary ion mass spectroscopy analysis. The chamber used for these experiments was an AKT 1600 PECVD, susceptor size 400 mm×500 mm (Applied Materials, Santa Clara, Calif.).

### EXAMPLE 1

### a-Si Pretreatment.

In this example, the PECVD chamber was pretreated with an a-Si seasoning process. A plasma was formed in the chamber at a pressure of 1.3 Torr and a temperature of 400° C. by passing 1400 standard centimeters per cubic centimeter (sccm) of hydrogen and 350 sccm of SiH₄ into the chamber for 180 seconds. The plasma was created from these gases using 300 Watts of power with a 13.56 MHz RF power generator. These process conditions resulted in the coating of a layer of amorphous silicon on the process chamber walls. The chamber was maintained at the temperature to be used for subsequent deposition, and a pressure of 1.3 Torr. The spacing between the substrate support and the gas manifold was 1460 mils. No substrate was present during this seasoning. That is, the pretreatment was performed without substrate before the actual multi-layer deposition on the substrate.

After pretreatment, the PECVD chamber was used to form the structure having the topology illustrated in FIG. 1. To make the structure having the topology illustrated in FIG. 1, a substrate was placed on the substrate support and three films were deposited, silicon nitride, silicon oxide, and amorphous silicon (SiN/SiO/a-Si). In the structure formed, the SiN layer (FIG. 1, 104) was 500 angstroms thick, the SiO layer (FIG. 1, 106) was 1000 angstroms thick, and the a-Si layer (FIG. 1, 108) was 2000 angstroms thick.

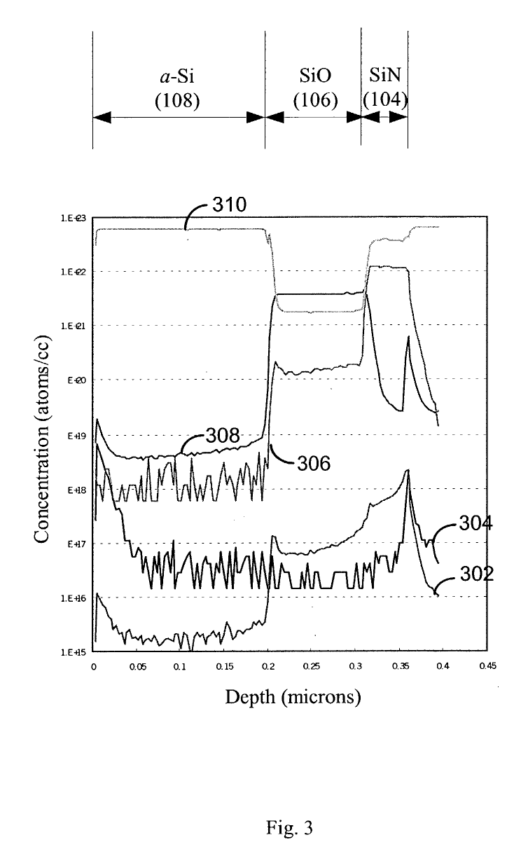

Secondary ion mass spectroscopy (SIMS) analysis of the a-Si layer (FIG. 1, 108) in this structure is shown in FIG. 3. These SIMS measurements were carried out on a commercial magnetic sector SIMS instrument using a cesium (Cs) primary ion beam and positive secondary ion mass spectrometry. Concentration calibration of oxygen (O), nitrogen (N), carbon (C) and fluorine (F) levels was achieved by using an ion implanted silicon material.

FIG. 3 shows the concentration of fluorine (curve 302), carbon (curve 304), nitrogen (curve 306), oxygen (curve 308), and silicon (curve 310) in the a-Silicon layer of the structure (FIG. 1, 108). The data shown in FIG. 3 demonstrates that the amount of contaminating oxygen (curve 308) in a-Si layer is less than 1×10¹⁹ atoms/cubic centimeter. This level of contaminating oxygen is acceptable for many applications and is, therefore, desirable.

### EXAMPLE 2

### SiO Pretreatment

The effect of the inventive a-Si seasoning (pretreatment) on impurity concentration level in a subsequently deposited a-Si film was compared with other types of pretreatment. In this example, the PECVD chamber was subjected to a SiO pretreatment prior to formation of a device having the topology illustrated in FIG. 1. In this SiO pretreatment, a plasma was formed in the chamber at a pressure of 1.5 Torr and a temperature of 400° C. by passing 200 standard centimeters per cubic centimeter (sccm) of SiH₄ gas, and 6000 sccm N₂O gas into the chamber for 180 seconds. The plasma was created from these gases using 800 Watts of power with a 13.56 MHz RF power generator. These process conditions resulted in the coating of a layer of amorphous silicon on the process chamber walls. The chamber was maintained at the temperature to be used for subsequent deposition, and a pressure of 1.5 Torr. The spacing between the substrate support and the gas manifold was 1460 mils. No substrate was present during this seasoning. That is, the pretreatment was performed without substrate before the actual multi-layer deposition on the substrate.

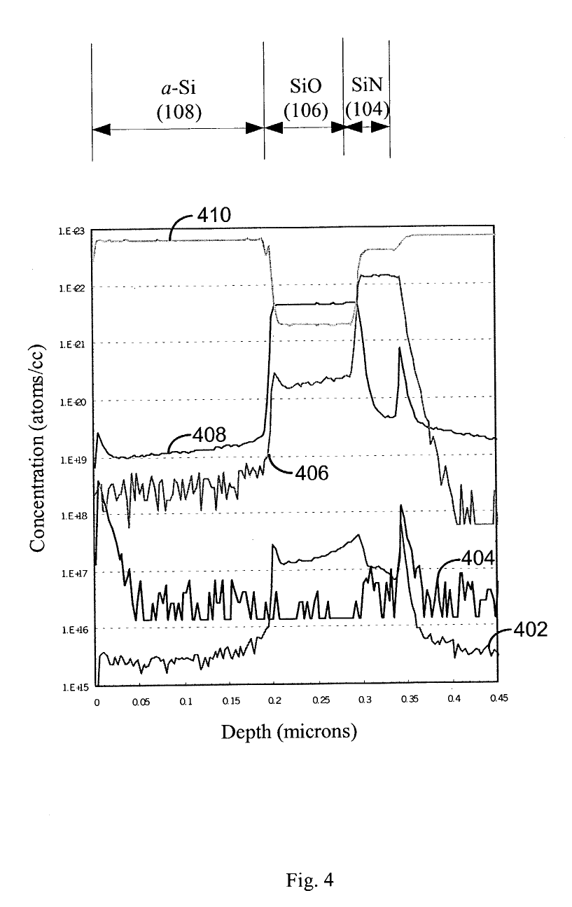

Thereafter, a substrate was deposited on the substrate support and filsm of silicon nitride, silicon oxide, and amorphous silicon were deposited. The SIMS analysis of the a-Si layer in the device formed in the chamber after SiO pretreatment is illustrated in FIG. 4. The equipment and method used to perform this SIMS analysis is the same as that disclosed for Example 1. FIG. 4 discloses the concentration of fluorine (curve 402), carbon (curve 404), nitrogen (curve 406), oxygen (curve 408), hydrogen (curve 410), and silicon (curve 412), in the a-Si layer (FIG. 1, 108). FIG. 4 shows that the amount of contaminating oxygen (curve 408) in the a-Si layer (FIG. 1, 108) exceeds 1×10¹⁹ atoms/cubic centimeter. Thus, unlike the case of the inventive a-silicon treatment (Example 1), silicon oxide pretreatment does not yield satisfactory results.

Comparison of Experiments 1 and 2. The concentration of contaminants in the a-Si layer (FIG. 1, 108) in the structures produced in Examples 1 and 2 are summarized in Table 1, below.

TABLE 1
COMPARISON OF EXPERIMENTS ONE AND TWO

| | O | N | C | F |
|---|---|---|---|---|
| Contaminant | (atoms/cc) | (atoms/cc) | (atoms/cc) | (atoms/cc) |
| After Non-a-Si | 1 × 10¹⁹ ˜ | 1 × 10¹⁸ ˜ | 1.5 × 10¹⁶ | 2 × 10¹⁵ ˜ |
| seasoning | 2 × 10¹⁹ | 8 × 10¹⁸ | 7 × 10¹⁶ | 6 × 10¹⁵ |
| (Example 2) | | | | |
| After a-Si | 3.5 × 10¹⁸ ˜ | 6 × 10¹⁷ ˜ | 1.5 × 10¹⁶ | 1 × 10¹⁵ ˜ |
| seasoning | 9 × 10¹⁸ | 4 × 10¹⁸ | 8 × 10¹⁶ | 3.5 × 10¹⁵ |
| (Example 1) | | | | |

As indicated in the comparison of the results in Table 1, a-Si seasoning (Example 1) reduces the concentration of oxygen and nitrogen in a-Si film relative to non a-Si seasoning (Example 2). A-Si seasoning (Example 1) results in an oxygen and nitrogen concentration that is below 1.0×10¹⁹ atoms/cc in the a-Si film. In some applications, 1.0×10¹⁹ atoms/cc is a maximum allowable concentration of oxygen and nitrogen contaminants in the a-Si layer. Thus, in some instances, the inventive a-Si pretreatment of the present invention allows for continuous multi-layer deposition with one process chamber without a-Si contamination problems. Without a-Si seasoning pretreatment, one process chamber cannot be used for multi-layer deposition due to the high level of contamination of oxygen in a-Si film.

Overview of A-Si seasoning pretreatment methods. In the methods of the present invention, a PECVD reactor is preseasoned with amorphous silicon. In some embodiments, plasma is formed in the PECVD chamber at a pressure of between 0.5 Torr and 6.0 Torr. In some embodiments, a plasma is formed in the PECVD chamber at a pressure of between 1.0 Torr and 2.0 Torr. In still other embodiments, plasma is formed in the PECVD chamber at a pressure of between 1.2 Torr and 1.5 Torr. In still other embodiments, plasma is created in the PECVD chamber at any pressure that will allow for the creation of an a-Si coating in the PECVD chamber.

During the seasoning step of the present invention, the susceptor in the PECVD chamber is held at a temperature between 275° C. and 475° C. In some embodiments, the susceptor in the PECVD chamber is held at a temperature between 325° C. and 450° C. during the seasoning step. In still other embodiments, the susceptor in the PECVD chamber is held at a temperature between 375° C. and 425° C. during the seasoning step. In one embodiment, the susceptor in the PECVD chamber is held at a temperature of 400° C. during the seasoning step.

In the methods of the present invention, certain gases are passed into the PECVD chamber and used to form a plasma that deposits an a-Si layer on the PECVD chamber walls. Therefore, any gas or combination of gases that can be used to form a plasma that deposits an a-Si layer on the PECVD chamber walls is encompassed within the scope of the present invention.

The gas flow rates used to introduce these gases into the PECVD reaction chamber are dependent upon the size of the substrate in the PECVD reaction chamber. Gas flow rate ranges for an AKT 1600 PECVD, susceptor size 400 mm×500 mm (Applied Materials, Santa Clara, Calif.), have been determined. Gas flow rate ranges for other PECVD reactors can be derived from the ranges used for the AKT 1600 PECVD, susceptor size 400 mm×500 mm, as a linear function of substrate size. For example, in some embodiments, hydrogen gas is passed into the chamber of an AKT 1600 PECVD, susceptor size 400 mm×500 mm, during the inventive seasoning step at a gas flow rate between 1000 sccm and 2500 sccm. Therefore, more generally, the gas flow rate of hydrogen into the chamber of a PECVD chamber of a given PECVD setup is between C₁×1000 sccm and C₁×2500 sccm, where C₁=[size of the substrate in the given PECVD setup/200,000 mm²]. Here, the denominator of C₁ is 200,000 mm² because that is the square area of an AKT 1600 PECVD, susceptor size 400 mm×500 mm.

It is known to those of skill in the art that the gas flow rate for one PECVD setup may be scaled to a different sized PECVD setup based on the proportional substrate size in the two PECVD setups using the relationship provided in the example above. However, when scaling process conditions from one sized PECVD setup to another sized PECVD setup, it is advisable to optimize the process conditions for the new setup. Such experimentation is accomplished using techniques known in the art.

In some embodiments, hydrogen and SiH₄ gas are passed into the chamber of a PECVD setup during the inventive seasoning step. In some embodiments, the gas flow rate of hydrogen into the chamber during the seasoning step is between C₁×1000 sccm and C₁×2500 sccm, where C₁=[size of the substrate in the PECVD setup/200,000 mm²]. In some embodiments, the gas flow rate of hydrogen into the chamber during the seasoning step is between C₁×1200 sccm and C₁×1800 sccm. In one particular embodiment, the gas flow rate of hydrogen into the PECVD chamber is C₁×1400 sccm.

In some embodiments of the present invention, the gas flow rate of SiH₄ into the PECVD chamber is between C₁×100 sccm and C₁×600 sccm, where C₁=[size of the substrate in the PECVD setup/200,000 mm²]. In other embodiments of the present invention, the gas flow rate of SiH₄ into the PECVD chamber is between C₁×200 sccm and C₁×400 sccm. In one embodiment, the gas flow rate of SiH₄ into the PECVD chamber is C₁×350 sccm.

In some embodiments of the present invention the SiH₄/H₂ gas flow ratio is about 1:4 (e.g. 350 sccm±50 sccm of SiH₄ and 1400 sccm±50 sccm of H₂). In some embodiments of the present invention, the SiH₄/H₂ gas flow ratio is anywhere between 1:2 and 1:8.

In some embodiments in accordance with the present invention, the plasma created from the gases flowed into the chamber of an AKT 1600 PECVD, susceptor size 400 mm×500 mm (Applied Materials, Santa Clara, Calif.) is generated with 300 Watts of power using an RF power generator. The RF power generator in one embodiment of the present invention is a 13.56 MHz RF power generator. Those of skill in the art will appreciate that many other types of RF power generators may be used in accordance with the present invention and all such RF power generators are included within the scope of the present invention. In fact, generators other than RF generators may be used in the present invention.

Regardless of the type of power generator used, a feature of the a-Si seasoning step of the present invention is the wattage used to create the plasma that forms an a-Si layer on the chamber walls. As described above, in one embodiment of the present invention, 300 Watts of power is used to create this plasma in an AKT 1600 PECVD, susceptor size 400 mm×500 mm (Applied Materials, Santa Clara, Calif.). The amount of power used to create the plasma that coats the chamber walls is dependent upon the size of the size of the substrate in the PECVD setup. Power ranges for an AKT 1600 PECVD, susceptor size 400 mm×500 mm (Applied Materials, Santa Clara, Calif.), have been determined. Power ranges for other PECVD reactors can be derived from the ranges used for the AKT 1600 PECVD, susceptor size 400 mm×500 mm, as a linear function of substrate size. For example, in the case where 300 Watts of power is used to generate plasma in an AKT 1600 PECVD, susceptor size 400 mm×500 mm, the power used to generate the same plasma in a given PECVD setup would be C₁×300 Watts. Here, C₁=[size of the substrate in the given PECVD setup/200,000 mm²]. The denominator of C₁ is 200,000 mm² because that is the square area of an AKT 1600 PECVD, susceptor size 400 mm×500 mm.

In some embodiments, the power used to create the plasma is between C₁×200 Watts and C₁×1000 Watts, where C₁=[size of the substrate in the PECVD setup used/200,000 mm²]. In some embodiments, the power used to create the plasma is between C₁×400 Watts and C₁×700 Watts.

In some embodiments of the present invention, the duration of the seasoning step is in the range or 30 seconds to 400 seconds. That is, the plasma is struck for a period of between 30 seconds and 400 seconds. In some embodiments, the duration of the seasoning step is 60 seconds to 300 seconds. In still other embodiments, the seasoning step is for 140 seconds to 225 seconds. In one embodiment, the duration of the seasoning step is in the range or 160 seconds to 190 seconds.

Cleaning. The seasoning step of the present invention will result in the coating of the PECVD chamber walls with an a-Si layer. This layer provides advantages in reducing the amount of contaminants in a-Si layers subsequently deposited in the device. However, it is necessary to periodically clean the a-Si off the chamber walls. In one embodiment, the a-Si is cleaned off the chamber walls of an AKT 1600 PECVD, susceptor size 400 mm×500 mm (Applied Materials, Santa Clara, Calif.) using the following process conditions. A flow of 800 sccm of nitrogen trifluoride is established with the gas inlet valve wide open, with a susceptor-gas manifold spacing of 1600 mils. An RF power of 3000 Watts is applied to the gas manifold to produce a cleaning plasma. The length of time that the cleaning plasma is continued is dependent upon the number of substrates processed in the chamber between cleaning. For example, if cleaning is performed between each substrate (e.g., the device illustrated in FIG. 1) the cleaning step is performed for about 180 seconds. In another example, if the cleaning is performed between every five substrates, the cleaning plasma is continued for 900 seconds.

Other seasoning regimens. After the last substrate on which a layer is to be deposited is removed from the chamber illustrated in FIG. 2A, a standard fluorine-containing gas clean is first carried out in the chamber in a conventional manner. A flow of 800 sccm of nitrogen trifluoride is established with the gas inlet valve wide open, producing a pressure of 200 milliTorr in the chamber, with a susceptor-gas manifold spacing of 1600 mils. An RF power of 1600 Watts is applied to the gas manifold to produce a cleaning plasma. The cleaning plasma is struck for a period of about one minute for each 2000 angstroms of amorphous silicon film that had been previously deposited in the chamber. Cleaning plasma is additionally continued for about one minute for each 4000 angstroms of silicon nitride film previously deposited on the substrate within the chamber.

The following two step conditioning process is used to remove fluorine residues remaining after the above CVD chamber clean step and to deposit a thin, inactive solid compound film on the walls and fixtures of the chamber to encapsulate particles.

As an example of the present process, in a first conditioning step, a hydrogen plasma was formed in the chamber by passing 1200 sccm of hydrogen into the chamber for 30 seconds, creating a plasma using 300 Watts of power. The hydrogen plasma reacted with the fluorine present in the chamber, thereby forming HF that was readily removable via the chamber exhaust system. The chamber was maintained at the temperature to be used for subsequent deposition, and a pressure of 1.2 Torr. The spacing between the substrate support and the gas manifold was 1462 mils.

In a second conditioning step, a thin film of silicon nitride was deposited under the same spacing, temperature and pressure conditions, but increasing the power to 800 Watts and changing the gases. The silicon nitride film was deposited by passing 100 sccm of silane, 500 sccm of ammonia and 3500 sccm of nitrogen into the chamber for an additional 30 seconds.

The total time needed to condition the chamber for subsequent deposition processing is thus only about one minute. The thin silicon nitride film coats the walls and fixtures of the chamber, thereby encapsulating and sealing any remaining particles in the chamber after the cleaning step so they cannot fall onto the substrate to be processed. The deposited silicon nitride layer also reduces outgassing of wall materials and also further reduces any remaining fluorine-containing materials from the chamber.

The above process removes fluorine-containing residues and reduces the number of particles in the chamber with a minimum reduction in system throughput. Alternative single-step conditioning processes using the same amount of processing time have been tried. A single sixty second silicon nitride deposition process is effective for reducing particles, but is less effective for reducing fluorine residues. It also creates a thicker wall deposit that must be etched away in a subsequent cleaning step. A single fifty second step of forming a hydrogen plasma is effective for reducing fluorine residues, but is not effective for reducing particles. A single sixty second step of amorphous silicon deposition, formed by adding silane to the hydrogen plasma process, is effective for reducing fluorine residues because of the high hydrogen atom production. However, the particle reduction is not as effective as the silicon nitride deposition. Also, again, the amorphous silicon deposition would need to be removed in a subsequent cleaning step.

Alternative two-step conditioning processes using the same amount of processing time are not as effective either. A thirty second amorphous silicon deposition plus a 30 second silicon nitride deposition would be effective for reducing fluorine residues and particles. However, the added amorphous silicon wall deposit would need to be removed in a subsequent cleaning step.

Products manufactured using the inventive seasoning method. The present invention is further directed to devices manufactured in a chemical vapor deposition chamber that has been preseasoned using the methods of the present invention. In this aspect of the invention, multilayered devices that include an amorphous silicon layer can be sequentially deposited without an intervening cleaning or chamber transfer step.

In one embodiment, the present invention is directed to a device comprising an amorphous silicon film that has been manufactured in a chemical vapor deposition chamber (e.g. the AKT 1600 PECVD, susceptor size 400 mm×500 mm). In this embodiment, the chamber is conditioned by passing a deposition gas mixture into the chamber under reaction conditions so as to deposit a layer of amorphous silicon on the interior surfaces in the chamber prior to manufacturing the device in the chamber. In some embodiments, the device is a multilayer device that includes a layer of silicon nitride and a layer of silicon oxide in addition to the layer of amorphous silicon and each layer in the multilayer device is sequentially deposited without an intervening cleaning or chamber transferring step. In some embodiments, the device is a multilayer device that includes a layer of silicon oxide in addition to the layer of amorphous silicon and each layer in the multilayer device is sequentially deposited without an intervening cleaning or chamber transferring step. In some embodiments, the device is a multilayer device that includes a layer of silicon nitride in addition to the layer of amorphous silicon and each layer in the multilayer device is sequentially deposited without an intervening cleaning or chamber transferring step. In yet other embodiments, the device is a multilayer device that includes an insulating film in addition to the layer of amorphous silicon and each layer in the multilayer device is sequentially deposited without an intervening cleaning or chamber transferring step.

Conclusion. Although the present process has been described in terms of particular embodiments, it will be apparent to one skilled in the art that various changes in the gases, reaction conditions, and the like can be made and are meant to be included herein. The invention is to be limited only by the scope of the appended claims.

We claim:

1. A method of conditioning a chemical vapor deposition chamber comprising, prior to a deposition step on a substrate, passing a deposition gas mixture into the chamber under reaction conditions so as to deposit a layer of amorphous silicon on the interior surfaces in the chamber.

2. The method of claim 1 wherein said chemical vapor deposition chamber is a plasma enhanced chemical vapor deposition chamber.

3. The method of claim 1 wherein the pressure in the chamber is between 0.5 Torr and 6.0 Torr during a portion of said method of conditioning said chemical vapor deposition chamber.

4. The method of claim 1 wherein the pressure in the chamber is between 1 Torr and 2 Torr during a portion of said method of conditioning said chemical vapor deposition chamber.

5. The method of claim 1 wherein the pressure in the chamber is between 1.2 Torr and 1.5 Torr during a portion of said method of conditioning said chemical vapor deposition chamber.

6. The method of claim 1 wherein a susceptor in the chamber is held at a temperature between 275° C. and 475° C. during a portion of the method of conditioning the chemical vapor deposition chamber.

7. The method of claim 1 wherein a susceptor in the chamber is held at a temperature between 325° C. and 450° C. during a portion of the method of conditioning the chemical vapor deposition chamber.

8. The method of claim 1 wherein a susceptor in the chamber is held at a temperature between 375° C. and 425° C. during a portion of the method of conditioning the chemical vapor deposition chamber.

9. The method of claim 1 wherein said deposition gas mixture includes hydrogen and SiH₄ gas.

10. The method of claim 9, wherein a gas flow rate of said hydrogen into said chamber during a portion of said method of conditioning said chemical vapor deposition chamber is between C₁×1000 sccm and C₁×2500 sccm, where C₁=(size of the substrate in the chemical vapor deposition chamber/200,000 mm²).

11. The method of claim 9, wherein a gas flow rate of said hydrogen into said chamber during a portion of said method of conditioning said chemical vapor deposition chamber is between C₁×1200 sccm and C₁×1800 sccm, where C₁=(size of the substrate in the chemical vapor deposition chamber/200,000 mm²).

12. The method of claim 9, wherein a gas flow rate of said SiH₄ into said chamber during a portion of said method of conditioning said chemical vapor deposition chamber is between C₁×100 sccm and C₁×600 sccm, where C₁=(size of the substrate in the chemical vapor deposition chamber/200,000 mm²).

13. The method of claim 9, wherein a gas flow rate of said SiH₄ into said chamber during a portion of said method of conditioning said chemical vapor deposition chamber is between C₁×200 sccm and C₁×400 sccm, where C₁=(size of the substrate in the chemical vapor deposition chamber/200,000 mm²).

14. The method of claim 9, wherein the ratio between the gas flow rate of said SiH₄ and the gas flow rate of said hydrogen into said chamber during a portion of said method of conditioning said chemical vapor deposition chamber is about 1:4.

15. The method of claim 9, wherein the ratio between the gas flow rate of said SiH₄ and the gas flow rate of said hydrogen into said chamber during a portion of said method of conditioning said chemical vapor deposition chamber is between 1:2 and 1:8.

16. The method of claim 1, wherein a plasma is formed from said deposition gas mixture using between C₁×200 Watts and C₁×1000 Watts of power, where C₁=(size of the substrate in the chemical vapor deposition chamber/200,000 mm²).

17. The method of claim 1, wherein a plasma is formed from said deposition gas mixture using between C₁×400 Watts and C₁×700 Watts of power, where C₁32 (size of the substrate in the chemical vapor deposition chamber/200,000 mm²).

18. The method of claim 1, wherein said reaction conditions comprise generating a plasma for a duration of between 30 seconds and 400 seconds.

19. The method of claim 1, wherein said reaction conditions comprise generating a plasma for a duration of between 60 seconds and 300 seconds.

20. The method of claim 1, wherein said reaction conditions comprise generating a plasma for a duration of between 140 seconds and 225 seconds.

21. The method of claim 1 further comprising
depositing an a-Si layer on a substrate; and
cleaning said chemical vapor deposition chamber.

22. The method of claim 1 wherein said cleaning comprises:
passing nitrogen fluoride into said chamber;
generating a plasma of said nitrogen fluoride.

23. A device comprising an amorphous silicon film, wherein
said device is manufactured in a chemical vapor deposition chamber and wherein,
said chemical vapor deposition chamber is conditioned by passing a deposition gas mixture into the chamber under reaction conditions so as to deposit a layer of amorphous silicon on the interior surfaces in the chamber prior to manufacturing said device in said chamber.

24. The device of claim 23 wherein
said device is a multilayer device that includes a layer of silicon nitride and a layer of silicon oxide in addition to said layer of amorphous silicon, and wherein
said amorphous silicon layer, said layer of silicon nitride and said layer of silicon oxide are deposited on a substrate without an intervening cleaning or chamber transferring step.

25. The device of claim 23 wherein
said device is a multilayer device that includes a layer of silicon oxide in addition to said layer of amorphous silicon, and wherein
said amorphous silicon layer and said layer of silicon oxide are deposited on a substrate without an intervening cleaning or chamber transferring step.

26. The device of claim 23 wherein
said device is a multilayer device that includes a layer of silicon nitride in addition to said layer of amorphous silicon, and wherein
said amorphous silicon layer and said layer of silicon nitride are deposited on a substrate without an intervening cleaning or chamber transferring step.

27. The device of claim 23 wherein
said device is a multilayer device that includes an insulating film in addition to said layer of amorphous silicon, and wherein
said amorphous silicon layer and said insulating film are each sequentially deposited on a substrate without an intervening cleaning or chamber transferring step.
